(19) United States
(12) Patent Application Publication
(10) Pub. No.: US 2026/0007077 A1
(43) Pub. Date: Jan. 1, 2026

(54) SPIN-ORBIT TORQUE MAGNETIC RANDOM ACCESS MEMORY DEVICE AND MANUFACTURING METHOD THEREOF

(71) Applicant: United Microelectronics Corp., Hsin-Chu City (TW)

(72) Inventors: Hsiang-Chi Chien, Pingtung County (TW); Chih-Yueh Li, Taipei City (TW); Hsin-Jung Liu, Pingtung County (TW); Chau-Chung Hou, Kaohsiung City (TW); Ang Chan, Taipei City (TW); Chung-Yi Chiu, Tainan City (TW)

(73) Assignee: UNITED MICROELECTRONICS CORP., Hsin-Chu City (TW)

(21) Appl. No.: 18/789,732

(22) Filed: Jul. 31, 2024

(30) Foreign Application Priority Data
Jun. 27, 2024 (CN) 202410842136.0

(51) Int. Cl. H10N 50/80; G11C 11/16; H10B 61/00; H10N 50/01; H10N 50/10

(52) U.S. Cl. CPC H10N 50/80; G11C 11/161; H10B 61/00; H10N 50/01; H10N 50/10

(57) ABSTRACT

A spin-orbit torque magnetic random access memory device includes a dielectric layer, a magnetic tunneling junction structure, a spin-orbit torque layer, and bottom electrode. The dielectric layer is disposed above a substrate, and a first via hole penetrates through the dielectric layer in a vertical direction. The magnetic tunneling junction structure and the spin-orbit torque layer are disposed above the dielectric layer, and the magnetic tunneling junction structure is located on the spin-orbit torque layer. The bottom electrode is disposed above the substrate, and the bottom electrode is located under the spin-orbit torque layer. A first portion of the bottom electrode is disposed above the dielectric layer, and a second portion of the bottom electrode is disposed in the first via hole and directly connected with the first portion of the bottom electrode.

### BACKGROUND OF THE INVENTION

### 1. Field of the Invention

The present invention relates to a magnetic random access memory device and a manufacturing method thereof, and more particularly, to a spin-orbit torque magnetic random access memory (SOT-MRAM) device and a manufacturing method thereof.

### 2. Description of the Prior Art

There are essentially two types of data memory devices used in electronic products, non-volatile and volatile memory devices. Magnetic random access memory (MRAM) is a kind of non-volatile memory technology. Unlike current industry-standard memory devices, the MRAM uses magnetism instead of electrical charges to store data. In general, MRAM cells include a data layer and a reference layer. The data layer is composed of a magnetic material and the magnetization of the data layer can be switched between two opposing states by an applied magnetic field for storing binary information. The reference layer can be composed of a magnetic material in which the magnetization is pinned so that the strength of the magnetic field applied to the data layer and partially penetrating the reference layer is insufficient for switching the magnetization in the reference layer. During the read operation, the resistance of the MRAM cell is different when the magnetization alignments of the data layer and the reference layer are the same or not, and the magnetization polarity of the data layer can be identified accordingly. The structures of MRAM devices will vary depending on the technology used to magnetize the data layer. Currently, spin-transfer torque (STT) MRAM and spin-orbit torque (SOT) MRAM are relatively common technology.

### SUMMARY OF THE INVENTION

A spin-orbit torque magnetic random access memory device and a manufacturing method thereof are provided in the present invention. A structure and/or a position of a bottom electrode or a structure and/or a position of a spin-orbit torque layer may be adjusted for improving operation performance of the memory device.

According to an embodiment of the present invention, a spin-orbit torque magnetic random access memory device is provided. The spin-orbit torque magnetic random access memory device includes a dielectric layer, a magnetic tunneling junction structure, a spin-orbit torque layer, and a bottom electrode. The dielectric layer is disposed above a substrate, and a first via hole penetrates through the dielectric layer in a vertical direction. The magnetic tunneling junction structure is disposed above the dielectric layer. The spin-orbit torque layer is disposed above the dielectric layer, and the magnetic tunneling junction structure is located on the spin-orbit torque layer. The bottom electrode is disposed above the substrate, and the bottom electrode is located under the spin-orbit torque layer. A first portion of the bottom electrode is disposed above the dielectric layer, and a second portion of the bottom electrode is disposed in the first via hole and directly connected with the first portion of the bottom electrode.

According to another embodiment of the present invention, a spin-orbit torque magnetic random access memory device is provided. The spin-orbit torque magnetic random access memory device includes a dielectric layer, a magnetic tunneling junction structure, and a spin-orbit torque layer. The dielectric layer is disposed above a substrate, and a first via hole penetrates through the dielectric layer in a vertical direction. The magnetic tunneling junction structure is disposed above the dielectric layer, the spin-orbit torque layer is disposed above the substrate, and the magnetic tunneling junction structure is located on the spin-orbit torque layer. A first portion of the spin-orbit torque layer is disposed above the dielectric layer, and a second portion of the spin-orbit torque layer is disposed in the first via hole and directly connected with the first portion of the spin-orbit torque layer.

According to an embodiment of the present invention, a manufacturing method of a spin-orbit torque magnetic random access memory device is provided. The manufacturing method includes the following steps. A dielectric layer is formed above a substrate, and a via hole penetrates through the dielectric layer in a vertical direction. A magnetic tunneling junction structure and a spin-orbit torque layer are formed above the dielectric layer, and the magnetic tunneling junction structure is located on the spin-orbit torque layer. A bottom electrode is formed above the substrate, and the bottom electrode is located under the spin-orbit torque layer. A first portion of the bottom electrode is located above the dielectric layer, and a second portion of the bottom electrode is located in the via hole and directly connected with the first portion of the bottom electrode.

According to another embodiment of the present invention, a manufacturing method of a spin-orbit torque magnetic random access memory device is provided. The manufacturing method includes the following steps. A dielectric layer is formed above a substrate, and a via hole penetrates through the dielectric layer in a vertical direction. A magnetic tunneling junction structure is formed above the dielectric layer. A spin-orbit torque layer is formed above the substrate, and the magnetic tunneling junction structure is located on the spin-orbit torque layer. A first portion of the spin-orbit torque layer is located above the dielectric layer, and a second portion of the spin-orbit torque layer is located in the via hole and directly connected with the first portion of the spin-orbit torque layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a spin-orbit torque magnetic random access memory device according to a first embodiment of the present invention.

FIGS. 2-7 are schematic drawings illustrating a manufacturing method of the spin-orbit torque magnetic random access memory device according to the first embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6.

FIG. 8 is a schematic drawing illustrating a spin-orbit torque magnetic random access memory device according to a second embodiment of the present invention.

FIGS. 9-14 are schematic drawings illustrating a manufacturing method of the spin-orbit torque magnetic random access memory device according to the second embodiment of the present invention, wherein FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, and FIG. 14 is a schematic drawing in a step subsequent to FIG. 13.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

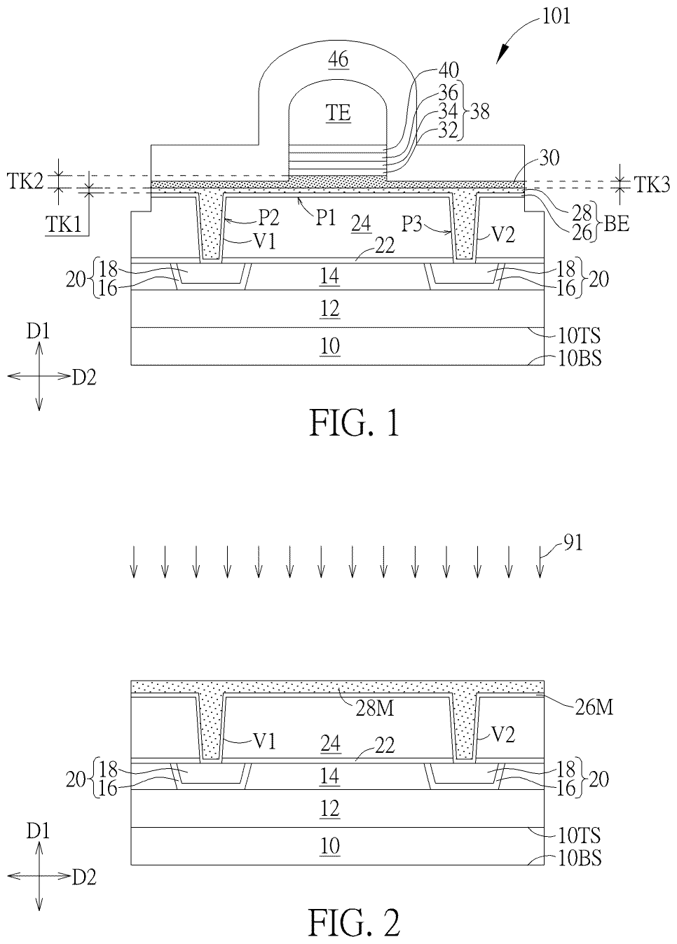

Please refer to FIG. 1. FIG. 1 is a schematic drawing illustrating a spin-orbit torque magnetic random access memory (SOT-MRAM) device (such as a SOT-MRAM device 101) according to a first embodiment of the present invention. As shown in FIG. 1, the SOT-MRAM device 101 includes a dielectric layer 24, a magnetic tunneling junction (MTJ) structure (such as a MTJ structure 38), a spin-orbit torque (SOT) layer (such as a SOT layer 30), and a bottom electrode BE. The dielectric layer 24 is disposed above a substrate 10, and a first via hole V1 penetrates through the dielectric layer 24 in a vertical direction D1. The MTJ structure 38 and the SOT layer 30 are disposed above the dielectric layer 24, and the MTJ structure 38 is located on the SOT layer 30. The bottom electrode BE is disposed above the substrate 10, and the bottom electrode BE is located under the SOT layer 30. A first portion P1 of the bottom electrode BE is disposed above the dielectric layer 24, and a second portion P2 of the bottom electrode BE is disposed in the first via hole V1 and directly connected with the first portion P1 of the bottom electrode BE. The related processes may be simplified, the electrical resistance of the bottom electrode BE may be reduced, and/or the operation performance of the SOT-MRAM device 101 may be improved by disposing the bottom electrode BE partly in the first via hole V1 and partly above the dielectric layer 24.

In some embodiments, the vertical direction D1 may be regarded as a thickness direction of the substrate 10, the substrate 10 may have a top surface 10TS and a bottom surface 10BS opposite to the top surface 10TS in the vertical direction D1, and the dielectric layer 24, the MTK structure 38, the SOT layer 30, and the bottom electrode BE described above may be disposed at the side of the top surface 10TS. Horizontal directions substantially orthogonal to the vertical direction D1 (such as a horizontal direction D2) may be substantially parallel with the top surface 10TS and/or the bottom surface 10BS of the substrate 10, but not limited thereto. In this description, a distance between the bottom surface 10BS of the substrate 10 and a relatively higher location and/or a relatively higher part in the vertical direction D1 may be greater than a distance between the bottom surface 10BS of the substrate 10 and a relatively lower location and/or a relatively lower part in the vertical direction D1. The bottom or a lower portion of each component may be closer to the bottom surface 10BS of the substrate 10 in the vertical direction D1 than the top or upper portion of this component. Another component disposed above a specific component may be regarded as being relatively far from the bottom surface 10BS of the substrate 10 in the vertical direction D1, and another component disposed under a specific component may be regarded as being relatively close to the bottom surface 10BS of the substrate 10 in the vertical direction D1. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

In some embodiments, the SOT-MRAM device 101 may further include a dielectric layer 12, a dielectric layer 14, a plurality of connection structures 20, and a stop layer 22. The dielectric layer 12 is disposed on the substrate 10, the dielectric layer 14 is disposed on the dielectric layer 12, and the connection structures 20 are disposed in the dielectric layer 14. The stop layer 22 may cover the connection structures 20 and the dielectric layer 14, the dielectric layer 24 is disposed on the stop layer 22, and the first via hole V1 may further penetrate through the stop layer 22 in the vertical direction D1. In some embodiments, a second via hole V2 may penetrate through the dielectric layer 24 and the stop layer 22 in the vertical direction D1, and the first via hole V1 and the second via hole V2 may be located at two opposite sides of the MTJ structure 38 in the horizontal direction D2, respectively. In other words, the MTJ structure 38 does not overlap the first via hole V1 and the second via hole V2 when viewed in the vertical direction D1. In addition, a third portion P3 of the bottom electrode BE may be disposed in the second via hole V2 and directly connected with the first portion P1 of the bottom electrode BE, and the second portion P2 and the third portion P3 of the bottom electrode BE may contact and be electrically connected with different connection structures 20. In some embodiments, the second portion P2 and the third portion P3 of the bottom electrode BE may extend in the vertical direction D1 respectively, and each of the connection structures 20 may be regarded as a trench conductor extending in a horizontal direction, but not limited thereto.

In some embodiments, the substrate 10 may include a semiconductor substrate or a non-semiconductor substrate. The semiconductor substrate may include a silicon substrate, a silicon germanium semiconductor substrate or a silicon-on-insulator (SOI) substrate, and the non-semiconductor substrate may include a glass substrate, a plastic substrate, or a ceramic substrate, but not limited thereto. For example, when the substrate 10 includes a semiconductor substrate, a plurality of field effect transistors (not shown), a dielectric layer covering the field effect transistors (such as the dielectric layer 12 and the dielectric layer 14), and the connection structures 20 electrically connected with the field effect transistors may be disposed on the semiconductor substrate according to some considerations. The second portion P2 and the third portion P3 of the bottom electrode BE may be electrically connected with a specific transistor and/or other circuits via the corresponding connection structures 20. In some embodiments, electrical current may be formed in the bottom electrode BE and the SOT layer 30 via the connection structures 20 located corresponding to the second portion P2 and the third portion P3 of the bottom electrode BE, and the magnetic moment and the magnetization effect influencing the MTJ structure 38 may be formed by the electrical current passing through the SOT layer 30.

The SOT layer 30 may include a SOT material, and the SOT material may be defined as a material capable of generating the spin Hall effect and/or a material with greater spin-orbit coupling strength, so as to generate spin-orbit torque on a free layer in the MTJ structure 38 and change the direction of the magnetic torque of the free layer. For example, the SOT material may include hafnium (Hf), rhenium (Re), ruthenium (Ru), gold (Au), platinum (Pt), tantalum (Ta), tungsten (W), iridium (Ir), palladium (Pd), an alloy of the materials described above (such as IrPt, PtAu, PtPd, BiSb, and so forth), a compound of the materials described above (such as PtS, WTe₂, and so forth), or other suitable materials (such as BiSb and BiₓSe₁₋ₓ). In some embodiments, because of the influence of related processes, a top surface of the SOT layer 30 without being covered by the MTJ structure 38 in the vertical direction D1 may be slightly lower than a top surface of the SOT layer 30 located under the MTJ structure 38 in the vertical direction D1, and a thickness TK3 of the SOT layer 30 without being covered by the MTJ structure 38 in the vertical direction D1 may be less than a thickness TK2 of the SOT layer 30 located under the MTJ structure 38 in the vertical direction D1, but not limited thereto.

In some embodiments, the MTJ structures 38 may include a free layer 32, a barrier layer 34, and a reference layer 36 stacked sequentially from bottom to top, and the SOT-MRAM device 101 may further include a cap layer 40, a top electrode TE, and a cap layer 46, but not limited thereto. The top electrode TE may be located directly above the MTJ structure 38 and the cap layer 40 in the vertical direction D1, the cap layer 40 is located between the top electrode TE and the MTJ structure 38 in the vertical direction D1, and a top surface of the top electrode TE may include a curved surface because of the influence of the manufacturing process characteristics, but not limited thereto. In addition, the cap layer 46 may cover and contact the top surface of the SOT layer 30, the sidewall of the MTJ structure 38, and a surface of the top electrode TE. In some embodiments, a protection layer (not illustrated) may be disposed between the sidewall of the MTJ structure 38 and the cap layer 46 according to some considerations, and the protection layer may be formed in the process of forming the MTJ structure 38 concurrently, but not limited thereto.

In some embodiments, the bottom electrode BE may include a barrier layer 26 and an electrically conductive layer 28. The electrically conductive layer 28 is disposed on the barrier layer 26, and the barrier layer 26 and the electrically conductive layer 28 are partly disposed in the first via hole V1, partly disposed in the second via hole V2, and partly disposed above the dielectric layer 24. The barrier layer 26 disposed in the first via hole V1 and the barrier layer 26 disposed in the second via hole V2 may be directly connected with the barrier layer 26 disposed on the top surface of the dielectric layer 24, and the electrically conductive layer 28 disposed in the first via hole V1 and the electrically conductive layer 28 disposed in the second via hole V2 may be directly connected with the electrically conductive layer 28 disposed on the top surface of the dielectric layer 24. The barrier layer 26 may include titanium, titanium nitride, tantalum, tantalum nitride, or other suitable electrically conductive barrier materials, and the electrically conductive layer 28 may include tungsten or other suitable electrically conductive materials. In some embodiments, the bottom electrode BE may consist of the barrier layer 26 and the electrically conductive layer 28, and the first portion P1, the second portion P2, and the third portion P3 of the bottom electrode BE may respectively consist of a part of the barrier layer 26 and a part of the electrically conductive layer 28.

Additionally, in some embodiments, the first via hole V1 and the second via hole V2 may be fully filled with the barrier layer 26 and the electrically conductive layer 28, the barrier layer 26 may directly contact the two connection structures 20 located corresponding to the first via hole V1 and the second via hole V2, and the barrier layer 26 and the electrically conductive layer 28 may be partly disposed above the dielectric layer 24 and located outside the first via hole V1 and the second via hole V2. In other words, there may be not any other materials disposed in the first via hole V1 and the second via hole V2 except the barrier layer 26 and the electrically conductive layer 28, but not limited thereto. In some embodiments, the barrier layer 26 may be disposed conformally on the top surface of the dielectric layer 24, the inner sidewall and the bottom of the first via hole V1, and the inner sidewall and the bottom of the second via hole V2. The thickness of the barrier layer 26 disposed in the first via hole V1 and the second via hole V2 (such as the minimum thickness of the barrier layer 26 located at the bottoms of the first via hole V1 and the second via hole V2) may be substantially equal to the thickness of the barrier layer 26 disposed above the dielectric layer 24, and the thickness of the electrically conductive layer 28 disposed in the first via hole V1 and the second via hole V2 in the vertical direction D1 may be greater than the thickness of the electrically conductive layer 28 disposed above the dielectric layer 24. Compared with disposing via conductors in the first via hole V1 and the second via hole V2 and forming a bottom electrode above the dielectric layer 24 and connected with the via conductors, the bottom electrode BE in this embodiment may extend to be located in the first via hole V1 and the second via hole V2 and integrated with the portion disposed above the dielectric layer 24 into a single structure. The related processes may be simplified and/or the electrical resistance of the bottom electrode BE may be reduced accordingly. Additionally, in some embodiments, a thickness TK1 of the first portion P1 of the bottom electrode BE may be less than the thickness TK2 and/or the thickness TK3 of the SOT layer 30, and the electrically conductive layer 28 may be made of a material with relatively low electrical resistivity for improving charge conversion efficiency and enhancing the operation performance of the SOT-MRAM device accordingly. In some embodiments, the electrically conductive layer 28 and the SOT layer 30 may respectively include tungsten, and the electrical resistivity of the SOT layer 30 may be lower than the electrical resistivity of the electrically conductive layer 28 because of the influence of process conditions and/or other property requirements. For example, the tungsten used as the electrically conductive layer 28 has to be formed by a manufacturing method with better gap-filling performance (such as a chemical vapor deposition process, but not limited thereto) because the first via hole V1 and the second via hole V2 have to be filled with the electrically conductive layer 28, the resistivity of the tungsten used as the SOT layer 30 may be lowered by suitable manufacturing method and/or process condition modification (such as modifying the process temperature, but not limited thereto), and the electrical resistivity of the SOT layer 30 may be lower than that of the electrically conductive layer 28 when the material of the electrically conductive layer 28 and the material of the SOT layer 30 are tungsten.

In some embodiments, the dielectric layer 12, the dielectric layer 14, and the dielectric layer 24 may include an oxide dielectric material, a low dielectric constant dielectric material (such as a dielectric material with dielectric constant lower than 2.9, but not limited thereto), or other suitable dielectric materials. The connection structure 20 may include a barrier layer 16 and an electrically conductive layer 18 disposed on the barrier layer 16. The barrier layer 16 may include titanium, titanium nitride, tantalum, tantalum nitride, or other suitable electrically conductive battier materials, and the electrically conductive layer 18 may include tungsten, copper, aluminum, titanium aluminide, cobalt tungsten phosphide, or other suitable electrically conductive materials with relatively low electrical resistivity. The stop layer 22 may include nitrogen doped carbide (NDC), silicon nitride, silicon carbon nitride (SiCN), or other suitable materials. The free layer 32 and the reference layer 36 may include ferromagnetic materials, such as iron, cobalt, nickel, cobalt-iron (CoFe), cobalt-iron-boron (CoFeB), or other suitable ferromagnetic materials. In some embodiments, the reference layer 36 and an antiferromagnetic layer (not illustrated) may constitute a pinned layer with fixed direction of magnetic torque. The antiferromagnetic layer may include antiferromagnetic materials, such as iron manganese (FeMn), platinum manganese (PtMn), iridium manganese (IrMn), nickel oxide (NiO), a cobalt/platinum (Co/Pt) multilayer, or other suitable antiferromagnetic materials. The barrier layer 34 may include insulation materials, such as magnesium oxide (MgO), aluminum oxide, or other suitable insulation materials. The top electrode TE may include tantalum, tantalum nitride, titanium, titanium nitride, platinum, copper, gold, aluminum, or other suitable electrically conductive materials. The cap layer 40 may include ruthenium (Ru), or other suitable electrically conductive materials, and the cap layer 46 may include silicon nitride or other suitable cap materials.

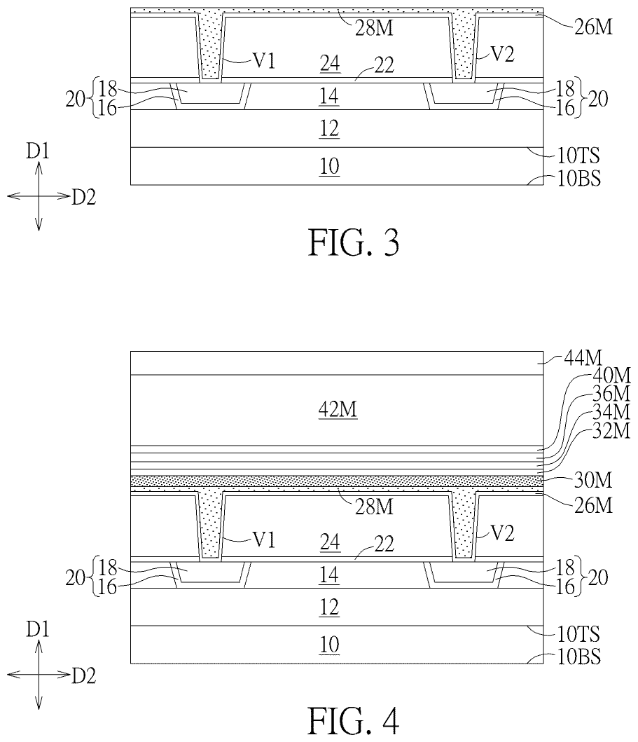

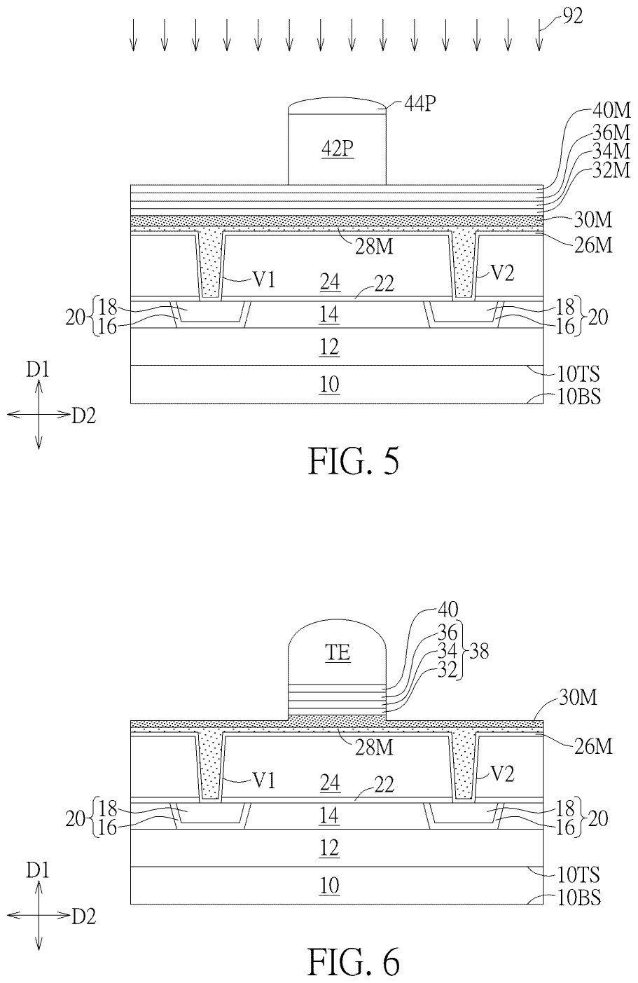

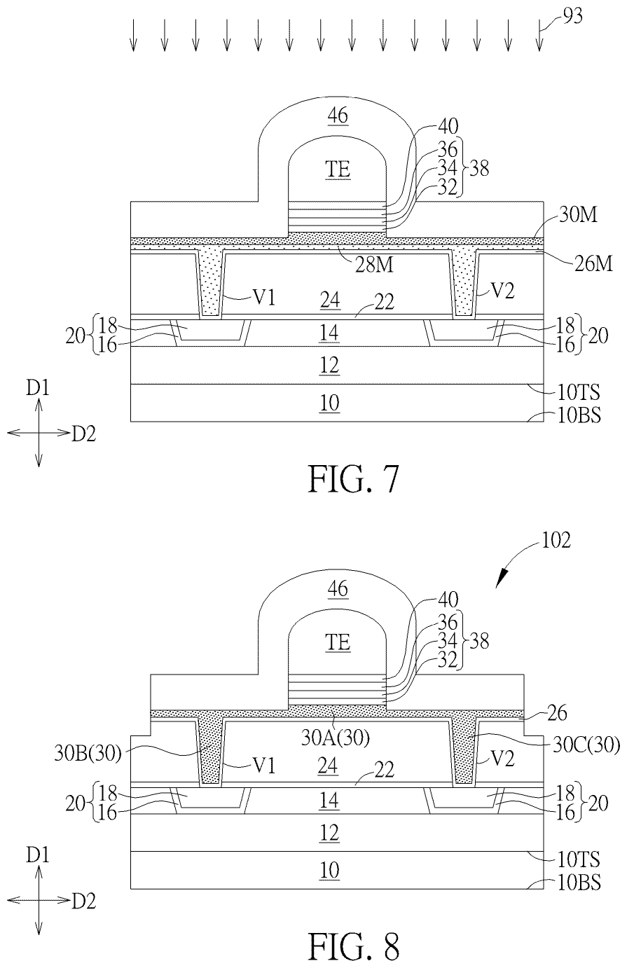

Please refer to FIGS. 1-7. FIGS. 2-7 are schematic drawings illustrating a manufacturing method of the spin-orbit torque magnetic random access memory device according to the first embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, and FIG. 7 is a schematic drawing in a step subsequent to FIG. 6. In some embodiments, FIG. 1 may be regarded as a schematic drawing in a step subsequent to FIG. 7, but not limited thereto. As shown in FIG. 1, the manufacturing method in this embodiment may include the following steps. The dielectric layer 24 is formed above the substrate 10, and a via hole (such as the first via hole V1) penetrates through the dielectric layer 24 in the vertical direction D1. The MTJ structure 38 and the SOT layer 30 are formed above the dielectric layer 24, and the MTJ structure 38 is located on the SOT layer 30. The bottom electrode BE is formed above the substrate 10, and the bottom electrode BE is located under the SOT layer 30. The first portion P1 of the bottom electrode BE is located above the dielectric layer 24, and the second portion P2 of the bottom electrode BE is located in the first via hole V1 and directly connected with the first portion P1 of the bottom electrode BE.

Specifically, the manufacturing method in this embodiment may include but is not limited to the following steps. As shown in FIG. 2, active components (such as the transistors described above), passive components, or other required circuit structures may be formed on the substrate 10, and the dielectric layer 12, the dielectric layer 14, the connection structures 20, the stop layer 22, and the dielectric layer 24 described above may then be formed. Subsequently, the first via hole V1 and the second via hole V2 may be formed penetrating through the dielectric layer 24 and the stop layer 2 in the vertical direction D1 and respectively exposing a part of the corresponding connection structure 20. A barrier material 26M may then be formed above the substrate 10, and an electrically conductive material 28M may be formed on the barrier material 26M. The barrier material 26M may be partly formed above the dielectric layer 24 and partly formed in the first via hole V1 and the second via hole V2, and the electrically conductive material 28M may be partly formed above the dielectric layer 24 and partly formed in the first via hole V1 and the second via hole V2 also. In some embodiments, the first via hole V1 and the second via hole V2 may be fully filled with the barrier material 26M and the electrically conductive material 28M, the barrier material 26M may be formed conformally on the top surface of the dielectric layer 24 and the inner sidewalls and the bottoms of the first via hole V1 and the second via hole V2, and the thickness of the electrically conductive material 28M may be greater than the thickness of the barrier material 26M. In some embodiments, the electrically conductive material 28M may be formed by a chemical vapor deposition process or other suitable manufacturing method with better gap-filling performance, but not limited thereto.

As shown in FIG. 2 and FIG. 3, an etching back process 91 may be performed to the electrically conductive material 28M for adjusting the thickness of the electrically conductive material 28M formed above the dielectric layer 24. In other words, the electrically conductive material 28M formed above the dielectric layer 24 may be thinned by the etching back process 91, but the electrically conductive material 28M located above the top surface of the dielectric layer 24 is not completely removed. In some embodiments, the electrically conductive material 28M and the electrically conductive layer formed of the electrically conductive material 28M in the subsequent process may have a flat top surface because of the deposition process of forming the electrically conductive material 28M and/or the effect of the etching back process 91. Subsequently, as shown in FIG. 4, a spin-orbit torque material (such as a SOT material 30M), a ferromagnetic material 32M, a barrier material 34M, a ferromagnetic material 36M, a cap material 40M, an electrically conductive material 42M, and a mask material 44M may be sequentially formed on the electrically conductive material 28M. It is worth noting that, compared with disposing via conductors in the first via hole V1 and the second via hole V2 and additionally forming a bottom electrode above the dielectric layer 24 and connected with the via conductors, a chemical mechanical polishing process performed to the electrically conductive material 28M and the barrier material 26M for removing the electrically conductive material 28M and the barrier material 26M located outside the first via hole V1 and the second via hole V2 is not required in the manufacturing method of this embodiment, and a step of forming additional conductive material (such as tantalum nitride, but not limited thereto) on the dielectric layer 24 and a chemical mechanical polishing process performed to this conductive material for forming a bottom electrode are not required in the manufacturing method of this embodiment also. Therefore, the process simplification may be realized and/or the overall electrical resistance of the bottom electrode may be reduced by the manufacturing method of this embodiment. Subsequently, as shown in FIG. 4 and FIG. 5, a patterning process (such as but not limited to a reactive ion etching (RIE) process) using a patterned mask layer (such as a patterned photoresist layer, not illustrated) as a mask may be performed to the mask material 44M and the electrically conductive material 42M for forming a patterned electrically conductive material 42P and a patterned mask material 44P. The mask material 44M may include an oxide mask material (such as silicon oxide) or other suitable mask materials.

As shown in FIG. 5 and FIG. 6, an etching process 92 using the patterned electrically conductive material 42P and/or the patterned mask material 44P as a mask may be performed for partially removing the cap material 40M, the ferromagnetic material 36M, the barrier material 34M, and the ferromagnetic material 32M and forming the MTJ structure 38 including the reference layer 36, the barrier layer 34, and the free layer 32 and the cap layer 40 on the SOT material 30M. In some embodiments, the etching process 92 may include an ion beam etching (IBE) process or other suitable etching approaches, and the patterned electrically conductive material 42P may be partially etched by the etching process 92 to be the top electrode TE located above the MTJ structure 38. Additionally, in some embodiments, the top electrode TE may have a curved top surface protruding upwards by adjusting the process parameters of the etching process 92 for enhancing the sidewall etching efficiency in the IBE process, but not limited thereto. In some embodiments, the SOT material 30M may be partly etching by the etching process 92 without exposing the electrically conductive material 28M located under the SOT material 30M, and a top surface of the SOT material 30M without being covered by the MTJ structure 38 in the vertical direction D1 may be slightly lower than a top surface of the SOT material 30M located under the MTJ structure 38 in the vertical direction D1 accordingly. In some embodiments, the first via hole V1 and the second via hole V2 may be fully filled with the barrier material 26M and the electrically conductive material 28M before the MTJ structure 38 is formed and after the MTJ structure 38 is formed.

As shown in FIG. 7 and FIG. 1, after the MTJ structure 38 and the top electrode TE are formed, a cap layer 46 may be formed covering the SOT material 30M, the sidewall of the MTJ structure 38, and the top electrode TE. In some embodiments, after the etching process 92 described above in FIG. 5, a protection layer (not illustrated) may be formed by oxidizing the sidewall of the MTJ structure 38 in-situ, and the cap layer 46 may be formed in-situ also after the protection layer is formed, but not limited thereto. After the cap layer 46 is formed, a patterning process 93 may be performed to the cap layer 46, the SOT material 30M, the electrically conductive material 28M, and the barrier material 26M. The SOT material 30M may be patterned by the patterning process 93 to become the SOT layer 30, and the electrically conductive material 28M and the barrier material 26M may be patterned by the patterning process 93 to become the electrically conductive layer 28 and the barrier layer 26 constituting the bottom electrode BE. The patterning process 93 may include a photolithographic and etching process or other suitable patterning approaches. In some embodiments, the SOT layer 30 and the bottom electrode BE may be formed concurrently by the same process (such as the patterning process 93), but not limited thereto. In the manufacturing method described above, before the SOT layer 30 is formed, the barrier material 26M and the electrically conductive material 28M may be formed and the etching back process may be performed to the electrically conductive material 28M for adjusting the thickness of the electrically conductive material 28M. In some embodiments, the electrically conductive material 28M and the SOT layer 30 may respectively include tungsten, and the electrical resistivity of the SOT layer 30 may be lower than the electrical resistivity of the electrically conductive material 28M because of the influence of the process conditions and/or other property requirements, but not limited thereto. In addition, the method of forming the bottom electrode BE in this embodiment may include but is not limited to the steps shown in FIGS. 2-7 described above, and the bottom electrode BE illustrated in FIG. 1 may also be formed by other suitable approaches according to some design considerations.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

Please refer to FIG. 8. FIG. 8 is a schematic drawing illustrating a SOT-MRAM device 102 according to a second embodiment of the present invention. As shown in FIG. 8, the SOT-MRAM device 102 includes the dielectric layer 24, the magnetic tunneling junction structure (such as the MTJ structure 38), and the spin-orbit torque layer (such as the SOT layer 30). The dielectric layer 24 is disposed above the substrate 10, and the first via hole V1 penetrates through the dielectric layer 24 in the vertical direction D1. The MTJ structure 38 is disposed above the dielectric layer 24, the SOT layer 30 is disposed above the substrate 10, and the MTJ structure 38 is located on the SOT layer 30. A first portion 30A of the SOT layer 30 is disposed above the dielectric layer 24, and a second portion 30B of the SOT layer 30 is disposed in the first via hole V1 and directly connected with the first portion 30A of the SOT layer 30. As shown in FIG. 8 and FIG. 1, apart from the first embodiment described above, the SOT-MRAM device 102 does not include the bottom electrode BE in the first embodiment, and the SOT layer 30 in this embodiment may replace the electrically conductive layer 28 in the bottom electrode BE described above and extend into the first via hole V1 for further simplifying related processes and/or improving the operation performance of the SOT-MRAM device 102 by the lower resistance property of the SOT layer 30.

In some embodiments, the SOT-MRAM device 102 may further include the dielectric layer 12, the dielectric layer 14, the connection structures 20, the stop layer 22, the second via hole V2, the barrier layer 26, the cap layer 40, the top electrode TE, and the cap layer 46. A third portion 30C of the SOT layer 30 is disposed in the second via hole V2 and directly connected with the first portion 30A of the SOT layer 30, and the barrier layer 26 is partly disposed above the dielectric layer 24 and partly disposed in the first via hole V1 and the second via hole V2. The SOT layer 30 is disposed on the barrier layer 26, and the SOT layer 30 is directly connected with the barrier layer 26. In some embodiments, the first via hole V1 and the second via hole V2 may be fully filled with the barrier layer 26 and the SOT layer 30, and the barrier layer 26 and the SOT layer 30 may be partly disposed above the dielectric layer 24 and located outside the first via hole V1 and the second via hole V2. In other words, there may be not any other materials disposed in the first via hole V1 and the second via hole V2 except the barrier layer 26 and the SOT layer 30, but not limited thereto.

In some embodiments, the barrier layer 26 may be disposed conformally on the top surface of the dielectric layer 24 and the inner sidewalls and the bottoms of the first via hole V1 and the second via hole V2. The thickness of the barrier layer 26 disposed in the first via hole V1 and the second via hole V2 (such as the minimum thickness of the barrier layer 26 located at the bottoms of the first via hole V1 and the second via hole V2) may be substantially equal to the thickness of the barrier layer 26 disposed above the dielectric layer 24, and the thickness of the SOT layer 30 disposed in the first via hole V1 and the second via hole V2 in the vertical direction D1 may be greater than the thickness of the SOT layer 30 disposed above the dielectric layer 24. In addition, the top surface of the SOT layer 30 without being covered by the MTJ structure 38 in the vertical direction D1 may be slightly lower than the top surface of the SOT layer 30 located under the MTJ structure 38 in the vertical direction D1 because of the influence of the related processes, but not limited thereto.

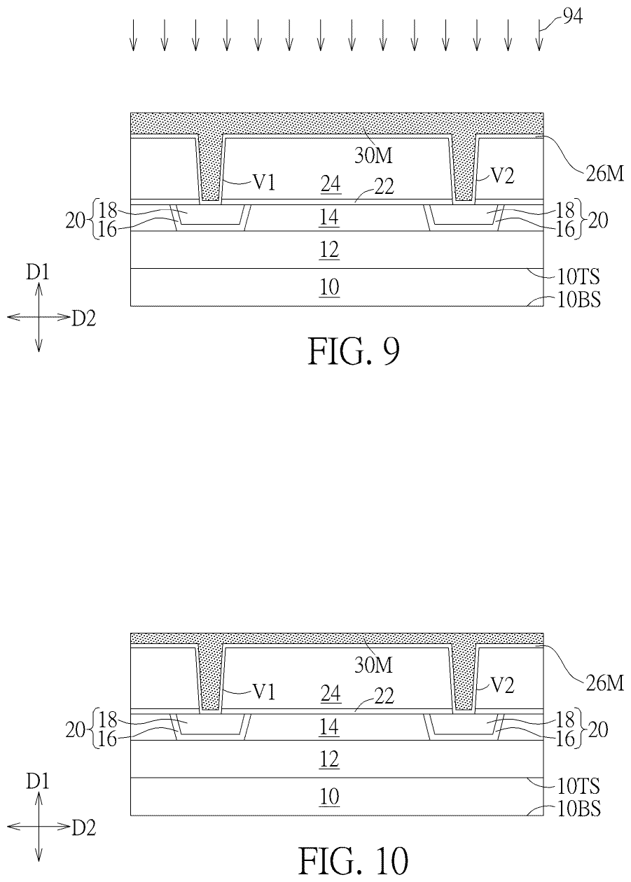

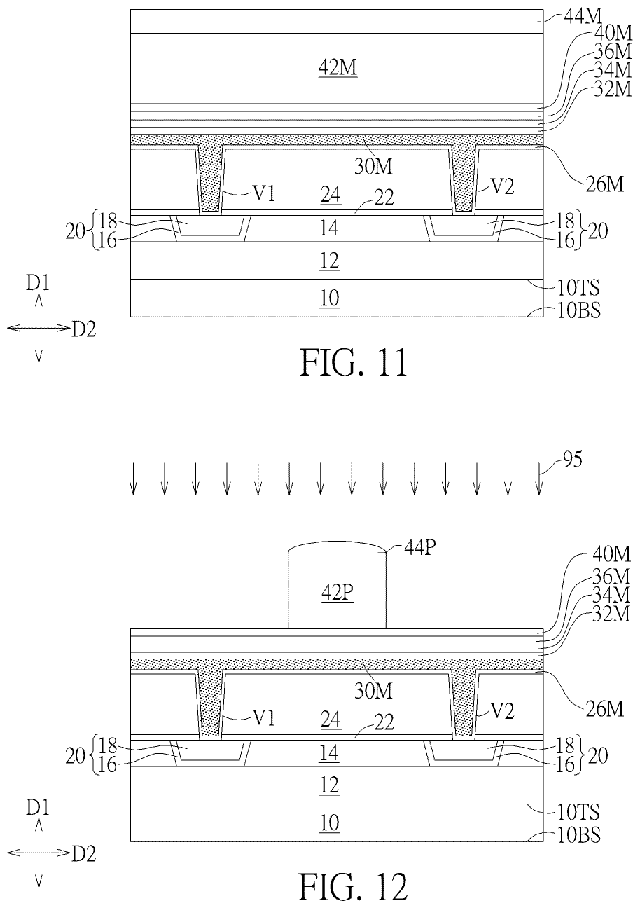

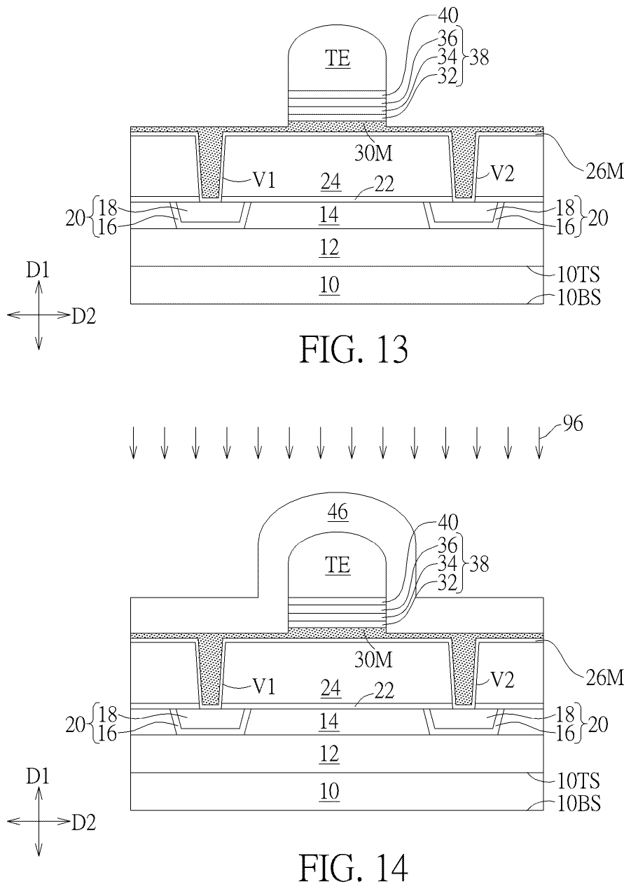

Please refer to FIGS. 8-14. FIGS. 9-14 are schematic drawings illustrating a manufacturing method of the spin-orbit torque magnetic random access memory device according to the second embodiment of the present invention, wherein FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, and FIG. 14 is a schematic drawing in a step subsequent to FIG. 13. In some embodiments, FIG. 8 may be regarded as a schematic drawing in a step subsequent to FIG. 14, but not limited thereto. As shown in FIG. 8, the manufacturing method in this embodiment may include the following steps. The dielectric layer 24 is formed above the substrate 10, and a via hole (such as the first via hole V1) penetrates through the dielectric layer 24 in the vertical direction D1. The MTJ structure 38 is formed above the dielectric layer 24. The SOT layer 30 is formed above the substrate 10, and the MTJ structure 38 is located on the SOT layer 30. The first portion 30A of the SOT layer 30 is located above the dielectric layer 24, and the second portion 30B of the SOT layer 30 is located in the first via hole V1 and directly connected with the first portion 30A of the SOT layer 30.

Specifically, the manufacturing method in this embodiment may include but is not limited to the following steps. As shown in FIG. 9, the dielectric layer 12, the dielectric layer 14, the connection structures 20, the stop layer 22, and the dielectric layer 24 are formed on the substrate 10, and the first via hole V1 and the second via hole V2 may be formed penetrating through the dielectric layer 24 and the stop layer 22 in the vertical direction D1 and respectively exposing a part of the corresponding connection structure 20. Subsequently, the barrier material 26M may then be formed above the substrate 10, and the SOT material 30M may be formed on the barrier material 26M. The barrier material 26M may be partly formed above the dielectric layer 24 and partly formed in the first via hole V1 and the second via hole V2, and the SOT material 30M may be partly formed above the dielectric layer 24 and partly formed in the first via hole V1 and the second via hole V2 also. In some embodiments, the first via hole V1 and the second via hole V2 may be fully filled with the barrier material 26M and the SOT material 30M, and the thickness of the SOT material 30M is greater than the thickness of the barrier material 26M.

As shown in FIG. 9 and FIG. 10, an etching back process 94 may be performed to the SOT material 30M for adjusting the thickness of the SOT material 30M formed above the dielectric layer 24. In other words, the SOT material 30M formed above the dielectric layer 24 may be thinned by the etching back process 94, but the SOT material 30M located above the top surface of the dielectric layer 24 is not completely removed. Subsequently, as shown in FIG. 11, the ferromagnetic material 32M, the barrier material 34M, the ferromagnetic material 36M, the cap material 40M, the electrically conductive material 42M, and the mask material 44M may be sequentially formed on the SOT material 30M. As shown in FIG. 11 and FIG. 12, a patterning process (such as but not limited to a reactive ion etching process) may be performed to the mask material 44M and the electrically conductive material 42M for forming the patterned electrically conductive material 42P and the patterned mask material 44P.

As shown in FIG. 12 and FIG. 13, an etching process 95 using the patterned electrically conductive material 42P and/or the patterned mask material 44P as a mask may be performed for partially removing the cap material 40M, the ferromagnetic material 36M, the barrier material 34M, and the ferromagnetic material 32M and forming the MTJ structure 38 including the reference layer 36, the barrier layer 34, and the free layer 32 and the cap layer 40 on the SOT material 30M. In some embodiments, the etching process 95 may include an ion beam etching process or other suitable etching approaches, and the patterned electrically conductive material 42P may be partially etched by the etching process 95 to be the top electrode TE located above the MTJ structure 38. In some embodiments, the SOT material 30M may be partly etching by the etching process 95 without exposing the barrier material 26M located under the SOT material 30M, the top surface of the SOT material 30M without being covered by the MTJ structure 38 in the vertical direction D1 may be slightly lower than the top surface of the SOT material 30M located under the MTJ structure 38 in the vertical direction D1 accordingly, and the first via hole V1 and the second via hole V2 may be fully filled with the barrier material 26M and the SOT material 30M before and after the MTJ structure 38 is formed.

As shown in FIG. 14 and FIG. 8, after the MTJ structure 38 and the top electrode TE are formed, the cap layer 46 may be formed covering the SOT material 30M, the sidewall of the MTJ structure 38, and the top electrode TE. After the cap layer 46 is formed, a patterning process 96 may be performed to the cap layer 46, the SOT material 30M, and the barrier material 26M. The SOT material 30M may be patterned by the patterning process 96 to become the SOT layer 30, and the barrier material 26M may be patterned by the patterning process 96 to become the barrier layer 26. The patterning process 96 may include a photolithographic and etching process or other suitable patterning approaches. In some embodiments, the SOT layer 30 and the barrier layer 26 may be formed concurrently by the same process (such as the patterning process 96), but not limited thereto. In the manufacturing method described above, before the patterning process 96, the barrier material 26M and the SOT material 30M may be formed and the etching back process may be performed to the SOT material 30M for adjusting the thickness of the SOT material 30M. In addition, the method of forming the SOT layer 30 in this embodiment may include but is not limited to the steps shown in FIGS. 9-14 described above, and the SOT layer 30 illustrated in FIG. 8 may also be formed by other suitable approaches according to some design considerations.

To summarize the above descriptions, in the SOT-MRAM device and the manufacturing method thereof according to the present invention, the structure and/or the position of the bottom electrode may be adjusted or the structure and/or the position of the SOT layer may be adjusted for replacing the bottom electrode. The operation performance of the SOT-MRAM device may be improved and/or the related process steps may be simplified accordingly

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A spin-orbit torque magnetic random access memory device, comprising:
a dielectric layer disposed above a substrate, wherein a first via hole penetrates through the dielectric layer in a vertical direction;
a magnetic tunneling junction structure disposed above the dielectric layer;
a spin-orbit torque layer disposed above the dielectric layer, wherein the magnetic tunneling junction structure is located on the spin-orbit torque layer; and
a bottom electrode disposed above the substrate, wherein the bottom electrode is located under the spin-orbit torque layer, a first portion of the bottom electrode is disposed above the dielectric layer, and a second portion of the bottom electrode is disposed in the first via hole and directly connected with the first portion of the bottom electrode.

2. The spin-orbit torque magnetic random access memory device according to claim 1, wherein the bottom electrode comprises:
a barrier layer; and
an electrically conductive layer disposed on the barrier layer, wherein the barrier layer and the electrically conductive layer are partly disposed in the first via hole and partly disposed above the dielectric layer.

3. The spin-orbit torque magnetic random access memory device according to claim 2, wherein the first via hole is fully filled with the barrier layer and the electrically conductive layer.

4. The spin-orbit torque magnetic random access memory device according to claim 2, wherein the electrically conductive layer and the spin-orbit torque layer comprise tungsten, and electrical resistivity of the spin-orbit torque layer is lower than electrical resistivity of the electrically conductive layer.

5. The spin-orbit torque magnetic random access memory device according to claim 1, wherein a second via hole penetrates through the dielectric layer in the vertical direction, a third portion of the bottom electrode is disposed in the second via hole and directly connected with the first portion of the bottom electrode, and the first via hole and the second via hole are located at two opposite sides of the magnetic tunneling junction structure.

6. The spin-orbit torque magnetic random access memory device according to claim 1, wherein a thickness of the first portion of the bottom electrode is less than a thickness of the spin-orbit torque layer.

7. A spin-orbit torque magnetic random access memory device, comprising:
a dielectric layer disposed above a substrate, wherein a first via hole penetrates through the dielectric layer in a vertical direction;
a magnetic tunneling junction structure disposed above the dielectric layer; and
a spin-orbit torque layer disposed above the substrate, wherein the magnetic tunneling junction structure is located on the spin-orbit torque layer, a first portion of the spin-orbit torque layer is disposed above the dielectric layer, and a second portion of the spin-orbit torque layer is disposed in the first via hole and directly connected with the first portion of the spin-orbit torque layer.

8. The spin-orbit torque magnetic random access memory device according to claim 7, further comprises:
a barrier layer partly disposed in the first via hole and partly disposed above the dielectric layer, wherein the spin-orbit torque layer is disposed on the barrier layer.

9. The spin-orbit torque magnetic random access memory device according to claim 8, wherein the spin-orbit torque layer is directly connected with the barrier layer.

10. The spin-orbit torque magnetic random access memory device according to claim 8, wherein the first via hole is fully filled with the barrier layer and the spin-orbit torque layer.

11. The spin-orbit torque magnetic random access memory device according to claim 7, wherein a second via hole penetrates through the dielectric layer in the vertical direction, a third portion of the spin-orbit torque is disposed in the second via hole and directly connected with the first portion of the spin-orbit torque layer, and the first via hole and the second via hole are located at two opposite sides of the magnetic tunneling junction structure.

12. A manufacturing method of a spin-orbit torque magnetic random access memory device, comprising:
forming a dielectric layer above a substrate, wherein a via hole penetrates through the dielectric layer in a vertical direction;
forming a magnetic tunneling junction structure above the dielectric layer;
forming a spin-orbit torque layer above the dielectric layer, wherein the magnetic tunneling junction structure is located on the spin-orbit torque layer; and
forming a bottom electrode above the substrate, wherein the bottom electrode is located under the spin-orbit torque layer, a first portion of the bottom electrode is located above the dielectric layer, and a second portion of the bottom electrode is located in the via hole and directly connected with the first portion of the bottom electrode.

13. The manufacturing method of the spin-orbit torque magnetic random access memory device according to claim 12, wherein a method of forming the bottom electrode comprises:
forming a barrier material above the substrate before the spin-orbit torque layer is formed, wherein the barrier material is partly formed above the dielectric layer and partly formed in the via hole;
forming an electrically conductive material on the barrier material before the spin-orbit torque layer is formed, wherein the electrically conductive material is partly formed above the dielectric layer and partly formed in the via hole; and
performing a patterning process to the barrier material and the electrically conductive material, wherein the electrically conductive material and the barrier material are patterned to be the bottom electrode by the patterning process.

14. The manufacturing method of the spin-orbit torque magnetic random access memory device according to claim 13, wherein the via hole is fully filled with the barrier material and the electrically conductive material before and after the magnetic tunneling junction structure is formed.

15. The manufacturing method of the spin-orbit torque magnetic random access memory device according to claim 13, wherein the method of forming the bottom electrode further comprises:
performing an etching back process to the electrically conductive material before the spin-orbit torque layer is formed, wherein the electrically conductive material formed above the dielectric layer is thinned by the etching back process.

16. The manufacturing method of the spin-orbit torque magnetic random access memory device according to claim 13, wherein the electrically conductive material and the spin-orbit torque layer comprise tungsten, and electrical resistivity of the spin-orbit torque layer is lower than electrical resistivity of the electrically conductive material.

17. A manufacturing method of a spin-orbit torque magnetic random access memory device, comprising:
forming a dielectric layer above a substrate, wherein a via hole penetrates through the dielectric layer in a vertical direction;
forming a magnetic tunneling junction structure above the dielectric layer;
forming a spin-orbit torque layer above the substrate, wherein the magnetic tunneling junction structure is located on the spin-orbit torque layer, a first portion of the spin-orbit torque layer is located above the dielectric layer, and a second portion of the spin-orbit torque layer is located in the via hole and directly connected with the first portion of the spin-orbit torque layer.

18. The manufacturing method of the spin-orbit torque magnetic random access memory device according to claim 17, wherein a method of forming the spin-orbit torque layer comprises:
forming a barrier material above the substrate, wherein the barrier material is partly formed above the dielectric layer and partly formed in the via hole;
forming a spin-orbit torque material on the barrier material, wherein the spin-orbit torque material is partly formed above the dielectric layer and partly formed in the via hole; and
performing a patterning process to the barrier material and the spin-orbit torque material, wherein the spin-orbit torque material is patterned to be the spin-orbit torque layer by the patterning process.

19. The manufacturing method of the spin-orbit torque magnetic random access memory device according to claim 18, wherein the via hole is fully filled with the barrier material and the spin-orbit torque material before and after the magnetic tunneling junction structure is formed.

20. The manufacturing method of the spin-orbit torque magnetic random access memory device according to claim 18, wherein the method of forming the spin-orbit torque layer further comprises:
performing an etching back process to the spin-orbit torque material before the patterning process, wherein the spin-orbit torque material formed above the dielectric layer is thinned by the etching back process.
